(19) United States
(12) Patent Application Publication
(10) Pub. No.: US 2007/0132368 A1
(43) Pub. Date: Jun. 14, 2007

(54) METHOD FOR MANUFACTURING ORGANIC LIGHT-EMITTING DEVICE, ORGANIC LIGHT-EMITTING DEVICE, AND ELECTRONIC APPARATUS

(75) Inventors: Takayuki KUWAHARA, Suwa-shi, Nagano-ken (JP); Shinichi YOTSUYA, Suwa-shi, Nagano-ken (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/565,401

(22) Filed: Nov. 30, 2006

(30) Foreign Application Priority Data
Dec. 8, 2005 (JP) 2005-355430

(51) Int. Cl. H05B 33/00; H05B 33/10

(52) U.S. Cl. 313/503; 313/500; 313/506; 445/24; 427/66

(57) ABSTRACT

A method for manufacturing an organic light-emitting device includes preparing a substrate on one of the surfaces of which a plurality of individual electrodes is provided; forming frame-shaped partition walls partitioning the individual electrodes; forming organic semiconductor layers inside the respective partition walls, the organic semiconductor layers each containing a luminescent layer; forming a common electrode so that it overlaps the organic semiconductor layers and the partition walls; and forming narrow conductors on the partition walls by a plurality of times of vacuum deposition between the formation of the partition walls and the formation of the common electrode, the narrow conductors having the function to decease the electric resistance of the whole common electrode by contact with the common electrode. In forming the conductors, the conductors are formed in divided micro strip portions connected to each other using the same mask.

### BACKGROUND

1. Technical Field

The present invention relates to a method for manufacturing an organic light-emitting device, an organic light-emitting device, and an electronic apparatus.

2. Related Art

Organic electroluminescence (EL) elements each include an organic semiconductor layer held between a cathode and an anode and having a luminescent layer containing at least a fluorescent organic compound (luminescent material). In such elements, electrons and holes are injected into the luminescent layer to produce excitons by recombination, and light emission (fluorescence or phosphorescence) due to deactivation of the excitons is utilized for emitting light.

Such organic EL elements are characterized by being capable of plane emission at a low voltage of 10 V or less with a high luminance of about 100 to 100,000 cd/m² and emission of light ranging from blue to red light. Therefore, organic EL elements attract attention as elements to be provided in display devices (organic light-emitting devices) capable of realizing large-area full-color displays at low cost.

An example of organic light-emitting devices capable of realizing full-color displays is a top-emission organic light-emitting device 900 shown in FIG. 11, which includes individual anodes 920 corresponding to a plurality of thin film transistors (TFTs) 910 provided on a substrate, frame-shaped partition walls 930 partitioning the anodes 920, organic semiconductor layers 960 provided inside the respective partition walls 930 and each containing a luminescent layer 940 and a hole transport layer 950, and a cathode 970 provided as a common electrode to cover the organic semiconductor layers 960 and the partition walls 930, so that light is emitted from the cathode side.

In the organic light-emitting device 900 having the above-described configuration, the cathode 970 is preferably as thin as possible from the viewpoint of further increasing the luminous efficiency of organic EL elements 980. However, the resistance of the whole cathode 970 increases as the thickness of the cathode 970 decreases. Consequently, there occurs the need to set the drive voltage for the organic EL elements 980 to a higher value, thereby causing the problem of increasing the power consumption of the organic EL elements 980 and furthermore shortening the life thereof.

The problem caused by increasing the drive voltage of the organic EL elements 980 also occurs in a bottom-emission organic light-emitting device in which light is emitted from the anode side.

A proposed method for solving the problem is to provide a narrow auxiliary cathode on the upper surface of each partition wall 930 in such a manner that the narrow auxiliary cathodes contact the cathode 970, for decreasing the electric resistance of the whole cathode 970 (refer to, for example, Japanese Unexamined Patent Application Publication No. 2003-123988).

In the organic light-emitting device, the auxiliary cathodes are formed by vacuum deposition using a shadow mask (simply referred to as a “mask” hereinafter) for preventing or suppressing the organic semiconductor layers 960 from degrading or deteriorating with time due to absorption of atmospheric oxygen and moisture.

However, when a mask having apertures corresponding to the shape of an auxiliary cathode narrow pattern is formed, the apertures may be distorted or bent due to a decrease in rigidity of a base material of the mask. Therefore, the auxiliary cathodes formed using the mask are also distorted or bent in the same manner as the apertures. Under present conditions, consequently, the resistance of the cathode 970 is not sufficiently decreased.

### SUMMARY

An advantage of some aspects of the invention is that the invention provides a method for manufacturing an organic light-emitting device capable of precisely forming conductors such as auxiliary cathodes on partition walls which partition individual organic luminescent elements, an organic light-emitting device manufactured by the method and having high characteristics, and an electronic apparatus.

In accordance with an embodiment of the invention, a method for manufacturing an organic light-emitting device includes preparing a substrate on one of the surfaces of which a plurality of individual electrodes has been provided; forming frame-shaped partition walls partitioning the individual electrodes; forming organic semiconductor layers inside the respective partition walls, the organic semiconductor layers each containing a luminescent layer; forming a common electrode so that it overlaps the organic semiconductor layers and the partition walls; and forming narrow conductors on the partition walls by a plurality of times of vacuum deposition between the formation of the partition walls and the formation of the common electrode, the narrow conductors having the function to decease the electric resistance of the whole common electrode by contact with the common electrode. In forming the conductors, the conductors are formed in divided small strips connected to each other using the same mask.

Therefore, the method for manufacturing an organic light-emitting device is capable of precisely forming conductors such as auxiliary cathodes on the partition walls partitioning the organic luminescent elements.

The conductors are preferably linear and formed by moving the mask in a direction in which the conductors are formed, at each time of the vacuum deposition.

Therefore, the conductors are formed with excellent deposition accuracy.

The conductors are preferably formed by forming a plurality of micro portions to be linearly arranged and then further providing a plurality of micro portions to connect the ends of the micro portions.

As a result, the conductors are formed with excellent deposition accuracy.

Each of the micro portions preferably widens at both ends thereof.

In this case, it may be possible to securely overlap the ends of the adjacent micro portions in the width direction thereof.

It is preferable that the mask includes a support substrate and a plurality of chips fixed to the support substrate and having apertures corresponding to the respective micro portions, and the support substrate and the chips are made of materials having substantially the same thermal expansion coefficient.

When the support substrate and the chips are made of such materials, it may be possible to prevent the occurrence of distortion of the mask due to a difference in amount of thermal expansion between the support substrate and the chips during the formation of the conductors by vacuum deposition.

It is also preferable that the micro portions are linear and satisfy the relation 2(A+B)<d1<D1−2(A+B) wherein d1 is the width (μm) of the apertures, D1 is the width (μm) of the partition walls, A is alignment accuracy (μm) between the support substrate and the chips, and B is alignment accuracy (μm) between the mask and the substrates

Therefore, in forming the conductors using the mask, it may be possible to securely form the micro portions so that both ends of the adjacent micro portions overlap each other while preventing the adjacent micro portions from projecting from the tops of the partition walls in the width direction of the micro portions.

It is further preferable that the micro portions are linear and satisfy the relation d2>D2/X+2(A+B) wherein d2 is the length (μm) of the apertures, D2 is the length (μm) of the conductors, X is the division number of D2, A is alignment accuracy (μm) between the support substrate and the chips, and B is alignment accuracy (μm) between the mask and the substrate.

Therefore, in forming the conductors using the mask, it may be possible to securely form the micro portions so that both ends of the adjacent micro portions overlap each other in the long-axis direction thereof.

It is further preferable that the common electrode is formed using a transparent conductive material, and the conductors are formed using a metal material having a smaller electric resistance than that of the transparent conductive material.

In this case, the electric resistance of the whole common electrode is securely decreased.

In organic light-emitting device according to an embodiment of the invention is manufactured by the above-described manufacturing method.

Therefore, the organic light-emitting device includes organic luminescence elements decreased in power consumption and increased in lifetime.

It is preferable that the organic light-emitting device is a top-emission structure device including the individual electrodes serving as anodes, and the common electrode serving as a cathode.

In this case, it may be possible to securely decrease the power consumption of the organic luminescent elements provided in the organic light-emitting device and securely increase the lifetime of the organic luminescent elements.

An electronic apparatus according to an embodiment of the invention includes the organic light-emitting device.

In this case, the electronic apparatus has high reliability.

### BRIEF DESCRIPTION OF THE DRAWINGS

The invention will be described with reference to the accompanying drawings, wherein like numbers reference like elements.

FIG. 1 is a longitudinal sectional view of an active matrix display device including an organic light-emitting device according to an embodiment of the invention.

FIG. 2 is a plan view showing an arrangement of organic EL elements of the active matrix display device shown in FIG. 1.

FIGS. 3A and 3B are plan views showing other arrangements of organic EL elements.

FIG. 4 is a schematic perspective view showing an example of a mask used in a method for manufacturing an organic light-emitting device according to an embodiment of the invention.

FIG. 5 is an enlarged perspective view showing a principal portion of the mask shown in FIG. 4.

FIGS. 6A to 6D are longitudinal sectional views illustrating a method for forming auxiliary cathodes in the active matrix display device shown in FIG. 1.

FIGS. 7A and 7B are plan views illustrating a method for forming auxiliary cathodes in the active matrix display device shown in FIG. 1.

FIG. 8 is a perspective view showing the configuration of a mobile (or notebook-size) personal computer including an electronic apparatus according to an embodiment of the invention.

FIG. 9 is a perspective view showing the configuration of a cellular phone (including PHS) including an electronic apparatus according to an embodiment of the invention.

FIG. 10 is a perspective view showing the configuration of a digital still camera including an electronic apparatus according to an embodiment of the invention.

FIG. 11 is a longitudinal sectional view showing an example of general active matrix display devices.

### DESCRIPTION OF EXEMPLARY EMBODIMENTS

A method for manufacturing an organic light-emitting device, an organic light-emitting device, and an electronic apparatus according to embodiments of the invention will be described in detail below with reference to the accompanying drawings.

Prior to the description of a method for manufacturing an organic light-emitting device according to an embodiment of the invention, description is first made of an active matrix display device including an organic light-emitting device according to an embodiment of the invention.

<Organic Light-Emitting Device>

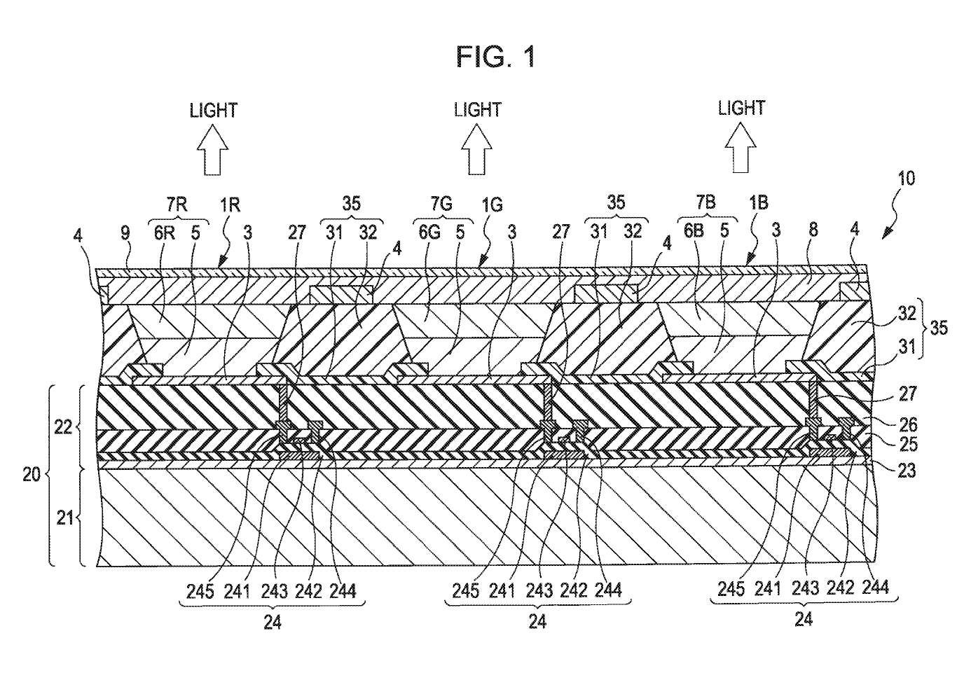

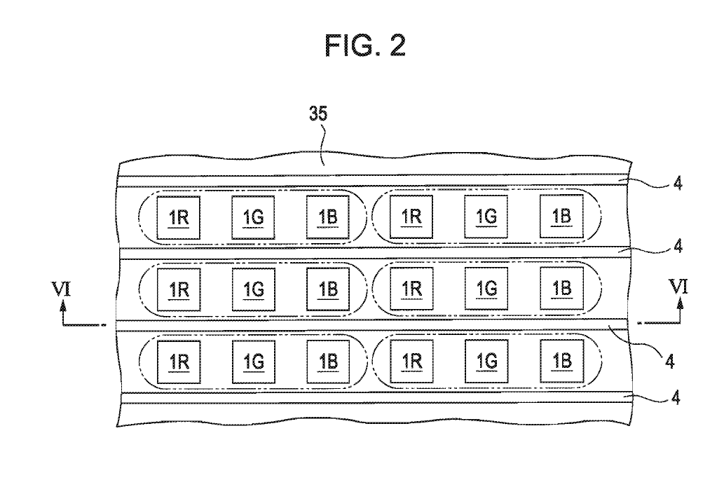

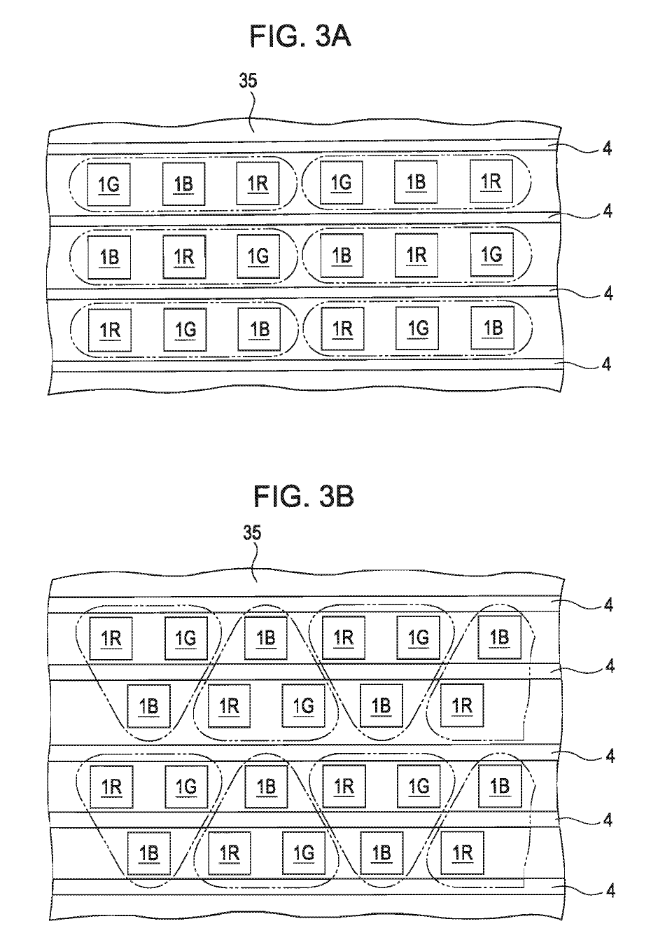

FIG. 1 is a longitudinal sectional view showing an active matrix display device including an organic light-emitting device according to an embodiment of the invention. FIG. 2 is a plan view showing an arrangement of organic EL elements of the active matrix display device shown in FIG. 1. FIGS. 3A and 3B are plan views showing other arrangements of organic EL elements. Hereinafter, “upper” means an upper portion of FIG. 1; and “lower”, a lower portion of FIG. 1.

An active matrix display device (simply referred to as a “display device” hereinafter) 10 shown in FIG. 1 includes a TFT circuit substrate 20 and organic EL elements 1R; 1G, and 1B emitting red light (R), green light (G), and blue light (B), respectively, partition walls 35 partitioning the respective organic EL elements 1R, 1G, and 1B, and an upper substrate 9 opposing the TFT circuit substrate 20, which are provided on the TFT circuit substrate 20.

A substrate 21 functions as a support for the components of the display device 10, and the upper substrate 9, for example, functions as a protective film or the like for protecting the organic EL elements (organic luminescence elements) 1R, 1G, and 1B.

The display device 10 according to this embodiment has a structure (top-emission type) in which light is emitted from the upper substrate side (cathode 8 descried below), and thus the upper substrate 9 is substantially transparent (colorless transparent, colored transparent, or translucent). On the other hand, the substrate 21 particularly need not be transparent.

Among various glass material substrates and resin substrates, a substrate having relatively high hardness is preferably used as the substrate 21.

On the other hand, a transparent substrate is selected as the upper substrate 9 from various glass material substrates and resin substrates. Examples of such a substrate include substrates mainly made of glass materials such as quartz glass and soda glass, and substrates mainly made of resin materials such as polyethylene terephthalate, polyethylene naphthalate, polypropylene, cycloolefin polymers, polyamides, polyethersulfone, polymethyl methacrylate, polycarbonate, and polyarylate.

The average thickness of the substrate 21 is not particularly limited, but preferably about 1 to 30 mm and more preferably about 5 to 20 mm. On the other hand, the average thickness of the upper substrate 9 is not particularly limited, but preferably about 0.1 to 30 mm and more preferably about 0.1 to 10 mm.

A circuit part 22 includes an underlying protective layer 23 formed on the substrate 21, driving TFTs (switching elements) 24 formed on the underlying protective layer 23, a first interlayer insulating layer 25, and a second interlayer insulating layer 26.

Each of the driving TFTs 24 includes a semiconductor layer 241, a gate insulating layer 242 formed on the semiconductor layer 241, a gate electrode 243 formed on the gate insulating layer 242, a source electrode 244, and a drain electrode 245.

The organic EL elements 1R, 1G, and 1B are provided on the circuit part 22 to correspond to the respective driving TFTs 24. The adjacent organic EL elements 1R, 1G, and 1B are divided by partition walls (banks) 35 each including a first partition wall 31 and a second partition wall 32.

In an organic light-emitting device according to an embodiment of the invention, narrow auxiliary cathodes (conductors) 4 are provided on the partition walls 35. In this embodiment, as shown in FIG. 2, a plurality of the auxiliary cathodes 4 is provided, and the auxiliary cathodes 4 have a linear shape.

The auxiliary cathodes 4 are formed in contact with a cathode 8, which will be described below, for decreasing the electric resistance of the whole cathode 8.

Therefore, as a constituent material for the auxiliary cathodes 4, it is preferable to use a conductive material having a lower electric resistance than that of a transparent conductive material used as a constituent material for the cathode 8.

Examples of such a conductive material include, but are not limited to, metal materials such as Al, Ni, Co, Cu, Ag, Au, and alloys thereof. These metal materials have higher conductivity than that of the transparent conductive material and securely decrease the electric resistance of the cathode 8 as a whole.

Among these metal materials, a material containing Al as a main component is particularly preferred as the constituent material for the auxiliary cathodes 4. Since Al exhibits excellent conductivity, is relatively inexpensive, and is easily deposited by vacuum deposition which will be described below, Al is preferably used as the constituent material for the auxiliary cathodes 4.

The average thickness of the auxiliary cathodes 4 is not particularly limited as long as it is smaller than the average thickness of the cathode 8, but is preferably about 10 to 2000 nm and more preferably about 300 to 1500 nm,. When the auxiliary cathodes 4 are excessively thin, the auxiliary cathodes 4 may not sufficiently function, while when the auxiliary cathodes 4 are excessively thick, a further effect may not be expected.

In this embodiment, an anode 3 of each of the organic EL elements 1R, 1G, 1B serves as an individual electrode (pixel electrode) and is electrically connected to the drain electrode 245 of the corresponding driving TFT 24 through wiring 27. In addition, organic semiconductor layers 7R, 7G, and 7B including hole transport layers 5 and luminescent layers 6R, 6G, and 6B, respectively, are separately formed for the organic EL elements 1R, 1G, and 1B, respectively, and the cathode 8 serves as a common electrode.

As shown in a plan view of FIG. 2, the organic EL elements 1R, 1G, and 1B are arranged in a matrix, and each portion (including three organic EL elements 1R, 1G, and 1B) surrounded by a two-dot chain line forms one pixel.

The arrangement of the organic EL elements 1R, 1G, and 1B is not limited to the arrangement shown in FIG. 2, and may be, for example, an arrangement shown in FIG. 3A or 3B. In this case, the linear auxiliary cathodes 4 are formed, for example, as shown in FIG. 3A or 3B.

The organic EL elements 1R, 1G, and 1B will be described in detail below.

As shown in FIG. 1, the organic EL elements 1R, 1G, and 1B include the individual anodes 3, the common cathode 8, and the individual organic semiconductor layers 7A, 7G, and 7B, respectively, which are provided between the anodes 3 and the cathode 8. In this embodiment, the organic semiconductor layers 7R, 7G, and 7B are laminates of the hole transport layers 5 and the luminescent layers 6R, 6G, and 6B, respectively, hole transport layers 5 and the luminescent layers 6R, 6G, and 6B being laminated in that order from the anode side.

Hereinafter, the organic EL elements 1R, 1G, and 1B may be generically named “the organic EL elements 1”, the organic semiconductor layer 7R, 7G, and 7B may be generically named “the organic semiconductor layers 7”, and the luminescent layers 6R, 6G, and 6B may be generically named “the luminescent layers 6”.

The anodes 3 are electrodes for injecting holes into the hole transport layers 5 (organic semiconductor layers 7).

The constituent material (anode material) for the anodes 3 is not particularly limited as long as it has conductivity, but is preferably a material having a high work function and excellent conductivity.

Examples of such a material include oxides such as ITO (composite of indium oxide and zinc oxide), SnO₂, Sb-containing SnO₂, and Al-containing ZnO; and Al, Ni, Co, Au, Pt, Ag, Cu, and alloys thereof. At least one of these materials may be used.

The average thickness of the anodes 3 is not particularly limited, but is preferably about 10 to 200 nm and more preferably 50 to 150 nm. When the anodes 3 are excessively thin, the anodes 3 may not sufficiently function, while when the anodes 3 are excessively thick, recombination of holes and electrons does not occur in the luminescent layers 6, thereby decreasing the characteristics, such as the luminous efficiency of the Organic EL elements 1, and the like.

As the anode material, for example, conductive resin materials such as polythiophene, polypyrrole, and the like may be used.

The anodes 3 preferably have light reflectivity. In this case, light emitted from the luminescent layers 6 described below is reflected to the upper substrate side without being absorbed (light absorption) by the anodes 3, thereby increasing the quantity of light transmitted through the upper substrate 9 (cathode 8). As a result, the characteristics such as the luminous efficiency and emission efficiency of the organic EL elements and the like may be improved.

In each of the anodes 3 having the above-described structure, at least the vicinity of the surface may be preferably composed of Al, Ni, Co, Ag, or an alloy thereof among the above-described anode materials.

On the other hand, the cathode 8 is an electrode for injecting electrons into the organic semiconductor layers 7 (luminescent layers 6).

Since the display device 10 has a top emission structure in which light is emitted from the cathode side, a transparent conductive material having transparency is selected as a constituent material (cathode material) for the cathode 8.

Examples of such a cathode material include transparent conductive materials such as indium tin oxide (ITO), fluorine-containing indigo tin oxide (FITO), antimony in oxide (ATO), indium zinc oxide (IZO), aluminum zinc oxide (AZO), tin oxide (SnO₂) zinc oxide (ZnO), fluorine-containing tin oxide (FTO), fluorine-containing indium oxide (FIO), and indium oxide (IO). These materials may be used alone or in combination or two or more.

The average thickness of the cathode 8 is not particularly limited but is preferably about 100 to 3000 nm and more preferably about 500 to 2000 nm. When the cathode 8 is excessively thin, the cathode 8 may not sufficiently function, while the cathode 8 is excessively thick, light transmittance decreases depending on the type of the cathode material used, and the organic EL elements having a top-emission type structure may become impractical.

The cathode 8 preferably has a transmittance of 60% or more and more preferably 80% or more in the visible region. Therefore, light is effectively emitted from the cathode side.

In order to secure such a transmittance, the thickness of the cathode 8 is set to as a small value as possible within the above-described range. Therefore, the resistance value of the cathode 8 is increased. Hence, when the formation of the auxiliary cathodes 4 is omitted, the drive voltage of the organic EL elements 1 is set to a high value, resulting in the problem of increasing the power consumption of the organic EL elements 1 and decreasing the life thereof. Furthermore, a terminal for applying a voltage between the anodes 3 and the cathode 8 is generally secured at the edge of the cathode 8. However, when the resistance of the cathode 8 is increased, it is difficult to uniformly control the emission of pixels (organic EL elements 1), i.e., simultaneously emit light from a plurality of pixels, due to different distances between the terminal and the organic EL elements 1 (luminescent layers 6).

On the other hand, when the auxiliary cathodes 4 are provided on the partition walls 35 so as to contact the cathode 8, the total electric resistance of the cathode 8 and the auxiliary cathodes 4, i.e., the electric resistance of the whole cathode 8, is decreased. As a result, the power consumption of the organic EL elements 1 is decreased, and furthermore the lifetime of the organic EL elements 1 is increased.

Furthermore, as shown in FIG. 2, the auxiliary cathodes 4 are linearly provided in substantially parallel to the direction perpendicular to the thickness direction of the cathode 8. Even when a voltage is applied between the anodes 3 and the cathode 8 through the terminal, therefore, a current (electrons) flow through the auxiliary cathodes 4 having excellent conductivity, thereby permitting substantially simultaneous emission of pixels (organic EL elements 1).

In addition, the organic semiconductor layers 7 are provided between the anodes 3 and the cathode 8. In this embodiment, each of the organic semiconductor layers 7 is a laminate of the hole transport layer 5 and the luminescent layer 6.

The hole transport layers 5 function to transport holes, which are injected from the anodes 3, to the luminescent layers 6.

Examples of a constituent material (hole transport material) for the hole transport layers 5 include compounds such as polyarylamine, fluorene-arylamine copolymers, fluorene-bithiophene copolymers, poly(N-vinylcarbazole), polyvinyl pyrene, polyvinyl anthracene, polythiophene, polyalkylthiophene, polyhexylthiophene, poly(p-phenylenevinylene), polyethylene vinylene, pyrene formaldehyde resin, and ethyl carbazole formaldehyde resin, and derivatives thereof. These compounds may be used alone or in combination of two or more.

The compounds may be used as mixtures with other compounds. Examples of a mixture containing polythiophene include poly(3,4-ethylenedioxythiophene/styrenesulfonic acid) (PEDOT/PSS), and the like.

The average thickness of the hole transport layers 5 is not particularly limited, but is preferably about 10 to 150 nm and more preferably 50 to 100 nm.

Furthermore, hole injection layers may be provided between the anodes 3 and the hole transport layers 5, for improving the efficiency of hole injection from the anodes 3.

Examples of a constituent material (hole injection material) for the hole injection layers include copper phthalocyanine, and 4,4′,4″-tris(N,N-phenyl-3-methylphenylamino)triphenylamine (m-MTDATA).

When a current is supplied (a voltage is applied) between the anodes 3 and the cathode 8, holes moving through the hole transport layers 4 and injected into the luminescent layers 6 and electrons injected into the luminescent layers 6 from the cathode 8 recombine in the luminescent layers 6. As a result, excitons are produced in the luminescent layers 6, and the excitons return to the ground state to emit energy (fluorescent or phosphorescent) (light emission).

Examples of a constituent material (luminescent material) for the luminescent layers 6 (6R, 6G, and 6B) include benzene compounds such as 1,3,5-tris[(3-phenyl-6-trifluoromethyl)quinoxalin-2-yl]benzene (TPQI) and 1,3,5-tris[{3-(4-tert-butylphenyl)-6-trifluoromethyl}quinoxalin-2-yl]benzene (TPQ2); metal or nonmetal phthalocyanine compounds, such as phthalocyanine, copper phthalocyanine (CuPc), and iron phthalocyanine; low-molecule compounds such as tris(8-hydoxyquinolinolate) aluminum (Alq₃) and fac-tris(2-phenylpyridine) iridium (Ir(ppy)₃); and polymer compounds such as oxadiazole polymers, triazole polymers, and carbazole polymers. These compounds may be used alone or in combination or two or more to obtain a target luminescent color.

Specific examples of a red luminescent material (constituent material for the luminescent layers 6R) include tris(1-phenylisoquinoline) iridium (III), poly[2,5-bis(3,7-dimethyloctyloxy)-1,4-phenylenevinylene], poly[2-methoxy-5-(2′-ethylhexyloxy)-1,4-(1-cyanovinylene)phenylene], and poly[2-methoxy-5-(3,7-dimethyloctyloxy)-1,4-phenylenevinylene].

Specific examples of a green luminescent material (constituent material for the luminescent layers 6G) include 9,10-bis[(9-ethyl-3-carbozole)-vinylenyl]-anthracene, poly(9,9-dihexyl-2,7-vinylenefluorenylene), poly(9,9-dioctylfluorene-2,7-diyl)-co-(1,4-diphenylene-vinylene-2-methoxy-5-{2-ethylhexyloxy}benzene)], and poly[(9,9-dioctyl-2,7-divinylenefluorenylene)-alt-co-(2-methoxy-5-(2-ethoxylhexyloxy)-1,4-phenylene)].

Specific examples of a blue luminescent material (constituent material for the luminescent layers 6B) include 4,4′-bis(9-ethyl-3-carbozovinylene)-1,1′-biphenyl, poly[(9,9-dioctylfluorene-2,7-diyl)-co-(2,5-dimethoxybenzene-1,4-diyl)], poly[(9,9-dihexyloxyfluorene-2,7-diyl)-alt-co-(2-methoxy-5-{2-ethoxyhexyloxy}phenylne-1,4-diyl)], and poly[(9,9-dioctylfluorene-2,7-diyl)-co-(ethylnylbenzene)].

The average thickness of each luminescent layer 6 is not particularly limited, but preferably about 10 to 150 nm and more preferably about 50 to 100 nm.

In addition, electron transport layers having the function to transport electrons, which are injected from the cathode 8, to the luminescent layers 6 may be provided between the cathode 8 and the luminescent layers 6. Furthermore, electron injection layers may be provided between the electron transport layers and the cathode 8, for improving the efficiency of electron injection to the electron transport layers from the cathode 8.

Examples of a constituent material (electron transport material) for the electron transport layers include various metal complexes such as complexes containing, as ligands, benzene compounds such as 1,3,5-tris[(3-phenyl-6-trifluoromethyl)quinoxalin-2-yl]benzene (TPQI), naphthalene compounds, phenanthrene compounds, chrysene compounds, perylene compounds, anthracene compounds, pyrene compounds, acridine compounds, stilbene compounds, thiophene compounds such as BBOT, bistyryl compounds, piperazine compounds such as distyrylpiperazine, quinoxaline compounds, benzoquinone compounds such as 2,5-diphenyl-para-benzoquinone, naphthoquinone compounds, anthraquinone compounds, oxadiazole compounds, triazole compounds such as 3,4,5-triphenyl-1,2,4-triazole, oxazole compounds, anthrone compounds, fluorenone compounds such as 1,3,8-trinitrofluorenone (TNF), diphenoquinone compounds such as MBDQ, stilbenequinone compounds such as MBSQ, anthraquinodimethane compounds, thiopyran dioxide compounds, fluorenylidene methane compounds, diphenyldicyanoethylene compounds, florene compounds, 8-hydroxyquinoline aluminum (Alq₃), benzoxazole, and benzothiazole. These compounds may be used alone or in combination of two or more.

The average thickness of the electron transport layers is not particularly limited, but preferably about 1 to 100 nm and more preferably about 20 to 50 nm.

Examples of a constituent material (electron injection material) for the electron injection layers include 8-hydroxyquinoline, oxadiazole, and derivatives thereof (e.g., metal chelate oxynoid compounds containing 8-hydroxyquinoline). These compounds may be used alone or in combination of two or more.

In this embodiment, description is made of the case in which the auxiliary cathodes 4 are provided in the top-emission display device 10 in which light is emitted from the upper substrate 9 (cathode 8) side. However, an embodiment is not limited to this, and auxiliary cathodes may be provided in a bottom-emission display device in which light is emitted Prom the TFT circuit substrate 20 (anode 3) side.

In the bottom-emission display device, the driving TFTs 24 are disposed on the TFT circuit substrate 20, and thus an emission area is limited, as compared with the top-emission display device. Namely, the opening ratio of the TFT circuit substrate 20 is deceased. In order to achieve higher luminance, the drive voltage of the organic EL elements is set to a higher value, thereby causing the problem of increasing the power consumption of the organic EL elements and decreasing the life thereof. When the auxiliary cathodes are provided in contact with the cathode of the bottom-emission display device, like in the top-emission display device, the drive voltage of the organic EL elements may be decreased, thereby resolving the above-mentioned problem.

Besides the display device 10 including the organic EL elements 1 each including the anode 3, the hole transport layer 5, the luminescent layer 6, and the cathode 8, which are laminated in that order on the TFT circuit substrate 20, as described in this embodiment, the invention may be applied to a display device including organic EL elements each including an individual luminescent layer, an individual hole transport layer, and a common anode, which are laminated in that order on the TFT circuit substrate 20. In this display device, auxiliary anodes may be provided as conductors on the partition walls 35 so as to contact the anodes 3, in order to decrease the electric resistance of the anode (common anode).

Furthermore, the display device 10 is not limited to a full color display in which the organic EL elements 1R, 1G, and 1B emit light of different colors (red, green, and blue), respectively, as described in this embodiment, and the display device 10 may be a monochrome (monocolor) display in which organic EL elements emit light of the same color (e.g., white).

<Method for Manufacturing Organic Light-Emitting Device>

The above-described display device 10 may be manufactured by a method for manufacturing an organic light-emitting device according to an embodiment of the invention as follows:

[1] First, the TFT circuit substrate 20 on which a plurality of anodes (Individual electrodes) 3 has been provided is prepared (first step).

[1-A] The substrate 21 is first prepared, and the underlying protective layer 23 is formed on the substrate 21 by plasma CVD or the like using, for example, TEOS (tetraethoxysilane) and oxygen gas as raw material gases, the underlying protective layer 23 having an average thickness of about 200 to 500 nm and being mainly composed of silicon oxide.

[1-B] Next, the driving TFTs 24 are formed on the underlying protective layer 23.

[1-Ba] First, a semiconductor film is formed on the underlying protective film 23 by, for example, plasma CVD or the like, under the condition in which the substrate 21 is heated to about 350° C., the semiconductor film having an average thickness of about 30 to 70 nm and being mainly composed of amorphous silicon.

[1-Bb] Next, the semiconductor film is crystallized by laser annealing or a solid-phase growth method to convert the amorphous silicon to polysilicon.

In laser annealing, for example, a line beam of excimer laser having a beam long dimension of 400 nm is used, and the output strength is set to, for example, about 200 mJ/cm². The line beam is scanned so that a portion of the beam having 90% of the peak laser strength in the short-dimension direction overlaps each region.

[1-Bc] Next, the semiconductor film is patterned in an island-like form, and the gate insulating films 242 are formed to cover the respective island-like semiconductor films 241 by plasma CVD or the like using, for example, TEOS (tetraethoxysilane) and oxygen gas as raw material gases, the gate insulating films having an average thickness of about 60 to 150 nm and being mainly composed of silicon oxide of silicon nitride.

[1-Bd] Next, a conductive film is formed on the gate insulating layers 242 by, for example, sputtering, the conductive film being mainly composed of a metal such as aluminum, tantalum, molybdenum, titanium, or tungsten. Then, the conductive film is patterned to form the gate electrodes 243.

[1-Be] Next, in this state, a high concentration of phosphorous ions is implanted to form source and drain regions in self-alignment in each of the gate electrodes 243. In this step, portions into which impurities were not implanted become channel regions.

[1-C] Next, the source electrode 244 and drain electrode 245 are formed to be electrically connected to each of the driving TFTs 24.

[1-Ca] First, the first interlayer insulating layer 25 is formed to cover the gate electrodes 243, and then contact holes are formed.

[1-Cb] Next, the source electrode 244 and the drain electrode 245 are formed in the respective contact holes.

[1-D] Next, the wiring (relay electrode) 27 is formed for electrically connecting the drain electrodes 245 and the anodes 3.

[1-Da] First, the second interlayer insulating layer 26 is formed on the first interlayer insulating layer 25, and contact holes are formed.

[1-Db] Next, the wiring is formed in each contact hole.

The TFT circuit substrate 20 is formed as described above.

[1-E] Next, a plurality of anodes (individual electrodes) 3 is formed on the second interlayer insulating layer 26 provided on the TFT circuit substrate 20 so that the anodes are in contact with the wiring 27 (first step).

The anodes 3 are formed by a method in which a conductive film mainly composed of the above-described constituent material for the anodes 3 is formed on the second interlayer insulating layer 26 by a vapor-phase deposition method, for example, vacuum deposition or sputtering, and then patterned.

[2] Next, the partition walls (bank) 35 are formed on the second interlayer insulating layer 26 so as to partition the anodes 3, i.e., partition regions for forming the respective organic EL elements 1R, 1G, and 1B (second step).

The partition walls 35 are formed by forming the first partition walls 31 on the second interlayer insulating layer 26 and then forming the second partition walls 32 on the first partition walls 31.

The first partition walls 31 are formed by forming an insulating film so that the anodes 3 and the second interlayer insulating film 26 are covered, and then patterning the insulating film by photolithography.

The second partition walls 32 are formed by forming an insulating film so that the anodes 3 and the first partition walls 31 are covered, and then patterning the insulating film by the same method as for the first partition walls 31.

Constituent materials for the first partition walls 31 and the second partition walls 32 are selected in view of heat resistance, liquid repellency, ink solvent resistance, adhesion to an underlying layer, and the like.

Examples of the constituent material for the first partition walls 31 include organic materials such as acrylic resins and polyimide resins; and inorganic materials such as SiO₂.

Examples of the constituent material for the second partition walls 32 include the above-described materials for the first partition walls 31, and fluorocarbon resins. By using a fluorocarbon resin, the water absorption resistance of the second partition walls 32 may be increased.

The shape of the apertures in the partition walls 35 may be any shape other than the square shape shown in FIG. 2, for example, a circular shape, an elliptical shape, or a polygonal shape such as a hexagonal shape.

When the apertures of the partition walls 35 are polygonal, the corners are preferably rounded. In this case, in forming the hole transport layers 5 and the luminescent layers 6 using liquid materials as described below, the liquid materials are securely supplied up to the corners of the spaces inside the partition walls 35.

The height of the partition walls 35 is not particularly limited and appropriately determined according to the total thickness of the anodes 3, the hole transport layers 5 and the luminescent layers 6, but preferably about 30 to 500 nm. With such a height, the partition walls (bank) sufficiently function.

[3] Next, the hole transport layer 5 and the luminescent layer 6 are laminated in that order on each of the anodes 3, i.e., inside each of the partition walls 35, to form the organic semiconductor layer 7 (third step).

[3-A] First, The hole transport layer 5 is formed on each of the anodes 3.

The hole transport layers 5 are formed by, for example, a vapor-phase process using sputtering, vacuum deposition, or CVD, or a liquid-phase process using spin coating (pyrosol), casting, micro gravure coating, gravure coating, bar coating, roll coating, wire bar coating, dip coating, spray coating, screen printing, flexographic printing, offset printing, or ink jet printing. In particular, the liquid-phase process using ink jet printing (droplet discharge) is preferred. By using ink jet printing, the hole transport layers 5 may be thinned to decrease the pixel size. Also, the liquid material for forming the hole transport layers may be selectively supplied inside the partition walls 35, thereby saving the liquid material.

Specifically, the liquid material for forming the hole transport layers is ejected from a head of an ink jet printer and supplied onto each of the anodes 3, and then if required, the liquid material is heated at about 150° C. within a short time after a solvent or dispersion medium is removed.

The solvent or dispersion medium is removed by a method of allowing in a reduced-pressure atmosphere, heat treatment (for example, about 50 to 60° C.), or a method using a flow of inert gas such as nitrogen gas. Furthermore, the residual solvent is removed by additional heat treatment (at about 150° C. within a short time).

The liquid material used is prepared by dissolving or dispersing the above-described hole transport material in a solvent or a dispersion medium.

Examples of the solvent or dispersion medium used for preparing the liquid material include inorganic solvents, such as nitric acid, sulfuric acid, ammonia, hydrogen peroxide, water, carbon disulfide, carbon tetrachloride, and ethylene carbonate; and organic solvents such as ketone solvents, e.g., methyl ethyl ketone (MEK), acetone, diethyl ketone, methyl isobutyl ketone (MIBK), methyl isopropyl ketone (MIPK), and cyclohexanone, alcohol solvents, e.g., methanol, ethanol, isopropanol, ethylene glycol, diethylene glycol (DEG), and glycerin, ether solvents, e.g., diethyl ether, diisopropyl ether, 1,2-dimethoxyethane (DME), 1,4-dioxane, tetrahydrofuran (THF), tetrahydropyran (THP), anisole, diethylene glycol dimethyl ether (diglyme), and diethylene glycol ethyl ether (carbitol), cellosolve solvents, e.g., methyl cellosolve, ethyl cellosolve, and phenyl cellosolve, aliphatic hydrocarbon solvents, e.g., hexane, pentane, heptane, and cyclohexane, aromatic hydrocarbon solvents, e.g., toluene, xylene, and benzene, aromatic heterocyclic compound solvents, e.g., pyridine, pyrazine, furan, pyrrole, thiophene, and methyl pyrrolidone, amide solvents, e.g., N,N-dimethylformamide (DMF) and N,N-dimethylactamide (DMA), halogenated compound solvents, e.g., dichloromethane, chloroform, and 1,2-dichloroethane, ester solvents, e.g., ethyl acetate, methyl acetate, and ethyl formate, sulfur compound solvents, e.g., dimethylsulfoxide (DMSO) and sulfolane, nitrile solvents, e.g., acetonitrile, propionitrile, and acrylonitrile, organic acid solvents, e.g., formic acid, acetic acid, trichloroacetic acid, and trifluoroacetic acid; and mixtures thereof.

The liquid material supplied on the anodes 3 has high fluidity (low viscosity) and tends to spread horizontally (planar direction). However, the anodes 3 are surrounded by the partition walls 35, and thus the liquid material is inhibited from spreading beyond a predetermined region, thereby precisely defining the contour shape of the hole transport layers 5 (organic EL elements 1).

[3-B] Next, the luminescent layer 6 is formed on each of the hole transport layers 5.

The luminescent layers 6 may also be formed by the vapor-phase process or liquid-phase process, but the liquid-phase process using an ink jet method (droplet discharge method) is preferred for the same reason as described above. The use of the ink jet method has the advantage that a plurality or luminescent layers 6R, 6G, and 6B are easily separately formed.

[4] Next, the linear auxiliary cathodes (conductor) 4 are formed on the partition walls 35 so as to contact the cathode 8 formed in the next step [5] (conductor forming step).

As described above, when the linear auxiliary cathodes 4, i.e., narrow conductors, are formed at a time (simultaneously) by vacuum deposition using a shadow mask (simply referred to as a “mask” hereinafter) having apertures corresponding to the auxiliary cathodes 4, the resulting auxiliary cathodes may be bent or distorted due to bending or distortion of the apertures.

On the other hand, in the method for manufacturing the organic light-emitting device according to the embodiment of the invention, the narrow conductors (in this embodiment, the linear auxiliary cathodes 4) are formed in divided micro strip portions, which are connected to each other, by a plurality of times of vacuum deposition using the same mask.

The mask used in the method for manufacturing the organic light-emitting device according to the embodiment of the invention has apertures corresponding to the divided shapes of a strip conductor. Therefore, at each time of vacuum deposition, the mask is moved to a direction in which the conductors are formed, thereby forming a conductor pattern.

Namely, in this embodiment, at each time of vacuum deposition, the mask having the apertures corresponding to the divided shapes of the linear auxiliary cathodes 4 is horizontally moved along the long-axis direction (longitudinal direction) of the auxiliary cathodes 4 to be formed, thereby forming the auxiliary cathodes 4.

The mask having the above-described structure is capable of preventing a decrease in rigidity of the base material of the mask and thus securely inhibiting the occurrence of bending or distortion of the apertures. Therefore, it may be possible to securely prevent the occurrence of bending or distortion in the auxiliary cathodes 4 to be formed, thereby forming the auxiliary cathodes 4 with high deposition accuracy. As a result, the electric resistance of the whole cathodes 8 is decreased, the power consumption of the organic EL elements 1 is decreased, and the lifetime thereof is increased.

First, description will be made of an example of the mask (mask 40) used in the method for manufacturing the organic light-emitting device according to the embodiment of the invention. Then, description will be made of a method for forming the linear auxiliary cathodes 4 by vacuum deposition using the mask 40.

By using the mask 40, each of the linear auxiliary cathodes 4 is formed by depositing a first micro portion 4a and a second micro portion 4b in the same shape in that order by two times of vacuum deposition.

(Mask)

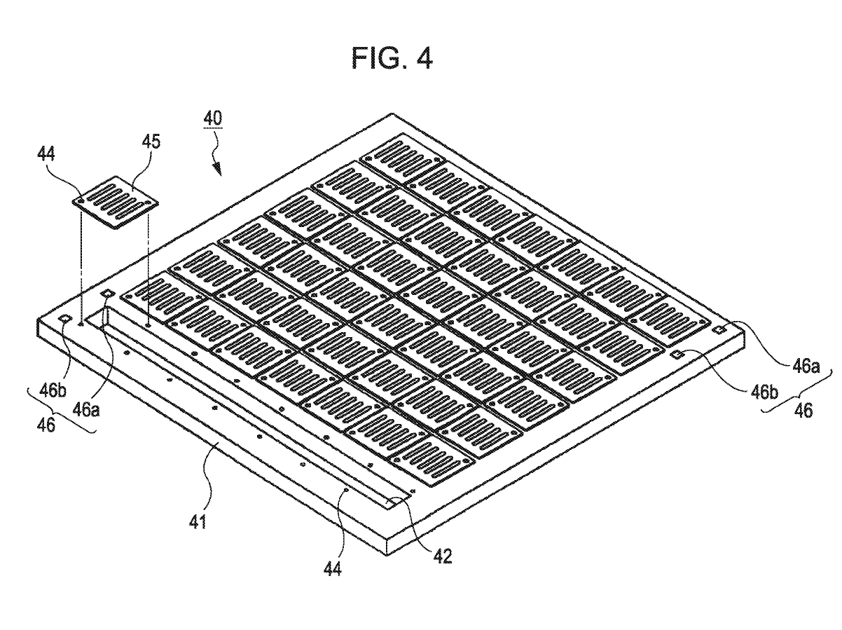

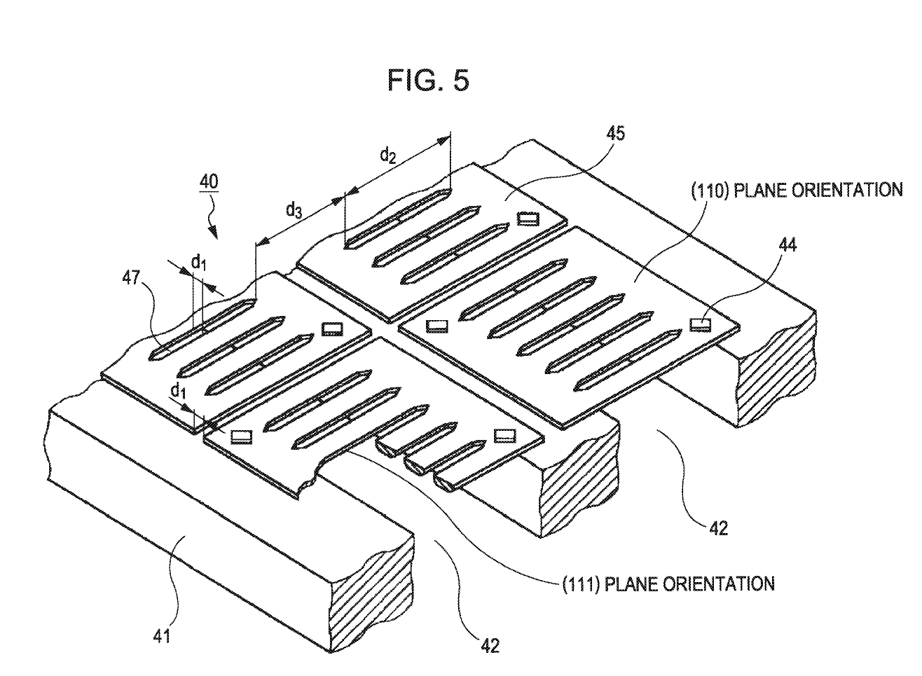

FIG. 4 is a schematic perspective view showing an example of the mask used in the method for manufacturing the organic light-emitting device according to the embodiment of the invention, and FIG. 5 is an enlarged perspective view showing a principal portion of the mask shown in FIG. 4.

As shown in FIGS. 4 and 5, a support substrate 41 has a rectangular planar shape and a plurality of aperture regions 42 passing through the support substrate 41 in the thickness direction thereof, the aperture regions 42 being provided in parallel along the longitudinal direction at a predetermined interval.

In the support substrate 41, alignment marks 44 are formed around each of the aperture regions 42, for aligning chips 45 with the support substrate 41 in mounting the chips 45. These alignment marks 44 are formed by photolithography or crystal anisotropic etching.

Furthermore, the support substrate 41 has mask positioning marks 46 formed in the periphery thereof, for positioning the mask 40 in the formation of the auxiliary cathodes 4 by vacuum deposition using the mask 40. The mask positioning marks 46 includes mask positioning marks 46a used in first vacuum deposition, and mask positioning marks 46b used in second vacuum deposition. The mask positioning marks 46 are composed of, for example, a metal film. The mask positioning marks 46 may be formed on the chips 45.

As a constituent material for the support substrate 41, a material having a thermal expansion coefficient which is substantially the same as (equal) or close to that of the constituent material (i.e., silicon) of the chips 45 is preferably used.

Specific examples of the constituent material for the support substrate 41 include Pyrex (trade name) glass manufactured by Corning Inc. which has substantially the same thermal expansion coefficient (30×10⁻⁷/° C.) as that of silicon (30×10⁻⁷/° C.), alkali-free glass OA-10 manufactured by Nippon Electric Glass Co., Ltd. which has a thermal expansion coefficient (38×10⁻⁷/° C.) close to that of silicon (30×10⁻⁷/° C.), and metal materials such as 42 alloy (thermal expansion coefficient 50×10⁻⁷/° C.) and Invar material (thermal expansion coefficient 12×10⁻⁷/° C.). When the support substrate 41 is formed using such a material, it may be possible to prevent the occurrence of distortion or bending of the mask 40 due to a difference in amount of thermal expansion between the support substrate 41 and the chips 45 during the formation of the auxiliary cathodes 4 by vacuum deposition.

A plurality of the chips 45 is bonded in alignment with the support substrate 41 using the alignment marks 44.

More specifically, a plurality of the chips 45 is arranged and bonded in a matrix at equal intervals on the support substrate 41 so as to cover the aperture regions 42. In this embodiment, as shown in FIG. 4, the chips 45 are arranged and bonded in seven rows and seven columns on the support substrate 41.

In each of the chips 45, as shown in FIG. 5, a plurality of through parts (apertures) 47 is formed corresponding to the shape and arrangement of some of the auxiliary cathodes 4 to be formed. In this embodiment, each of the through parts 47 has a linear planar shape corresponding to micro portions to be formed (the first micro portion 4a and the second micro portion 4b) and has an aperture passing through in the thickness direction. A plurality of through parts 47 is formed in parallel to each other at a predetermined interval.

Each of the through parts 47 extends perpendicularly to the longitudinal direction of the aperture regions 42 of the support substrate 41.

Also, as shown in FIG. 5, the width d1 of each through part 47 is substantially the same as the width of the auxiliary cathode 4 to be formed. The adjacent chips 45 covering the same aperture region 42 are arranged with a space therebetween, which equals to the width d1 of the auxiliary cathodes 4. Therefore, the spaces between the chips 45 have the same function as that of the through parts 47 of the chips 45 so that some of the auxiliary cathodes 4 are formed using the spaces.

Furthermore, the width d1 (μm) of the through parts 47 apertures) is preferably set to be larger than a value of 2(A+B) and smaller than a value of D1−2(A+B) wherein A (μm) is alignment accuracy between the support substrate 41 and the chips 45, B (μm) is alignment accuracy between the mask 40 and the TFT circuit substrate 20, and D1 (μm) is the width of the partition walls 35. In this case, in forming the auxiliary cathodes 4 using the mask 40, i.e., forming the first micro portions 4a and the second micro portions 4b, which will be describe below, using the mask 40, it may be possible to securely form the first micro portions 4a and the second micro portions 4b so that both ends overlap each other while preventing projection from the tops of the partition walls 35 in a direction perpendicular to the long-axis direction of the through parts 47.

Each of the through parts 47, i.e., each of the micro portions (first micro portions 4a and second micro portions 4b), preferably has a shape in which the width at both ends is larger than that of other portions (other than both ends). In this case, it may be possible to securely cause both ends of the adjacent micro portions (first micro portions 4a and second micro portions 4b) to overlap each other in the width direction of the through parts 47 (direction perpendicular to the long-axis direction thereof).

The length d2 of each through part 47 is substantially the same as or slightly larger than the length of divided equal parts (in this embodiment, 14 parts) of each auxiliary cathode 4 to be formed. The length d3 between the adjacent through parts 47 is also substantially the same as or slightly smaller than the length of divided equal parts of the auxiliary cathode 4 to be formed.

Furthermore, the length d2 (μm) of each through part 47 is preferably set to be larger than a value of D2/X+2(A+B) wherein D2 (μm) is the length of the auxiliary cathode 4 to be formed, X is a division number of D2, and, as described above, A (μm) is alignment accuracy between the support substrate 41 and the chips 45, and B (μm) is alignment accuracy between the mask 40 and the TFT Circuit substrate 20. In this case, in forming the first micro portions 4a and the second micro portions 4b, which will be described below, it may be possible to securely form the first and second micro portions 4a and 4b so that both ends overlap each other in the long-axis direction of the through parts 47.

Herein, the term “alignment accuracy” means a variation (standard deviation) from a position where the two alignment marks (mask positioning marks) are opposed to each other.

Each of the chips 45 includes a silicon single crystal substrate with a (110) plane orientation, and the longitudinal direction sides of each through part 47 of the chips 45 have a (111) plane orientation. The through parts 47 having the sides with a (111) plane orientation may be easily realized by crystal anisotropic etching of a silicon chip with a (110) plane orientation.

(Method for Forming Auxiliary Cathode)

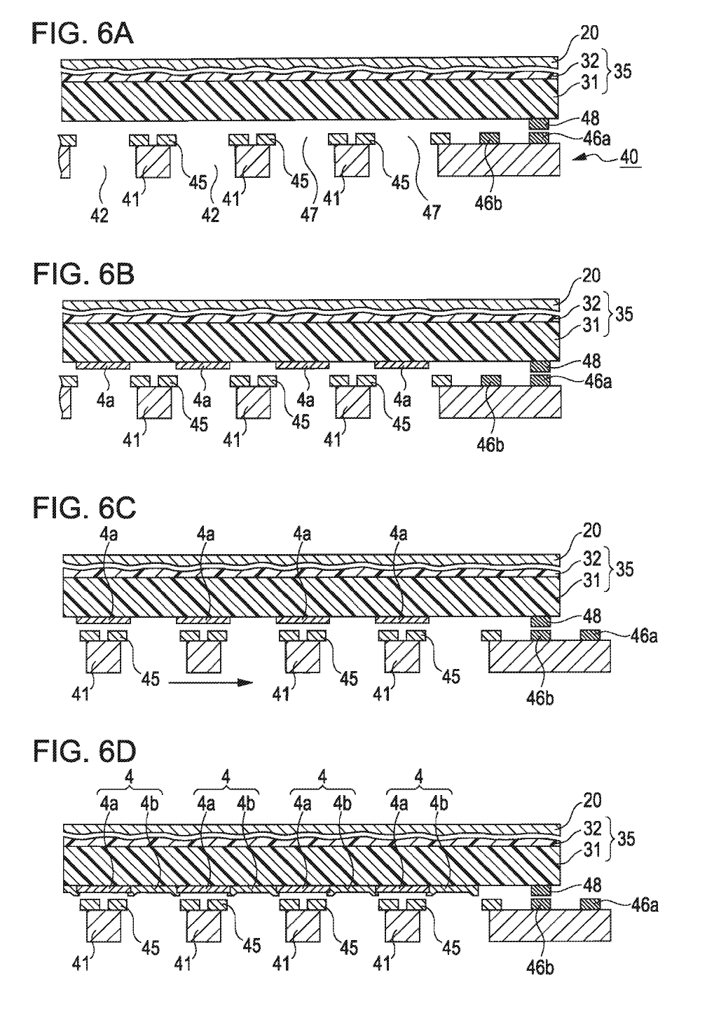

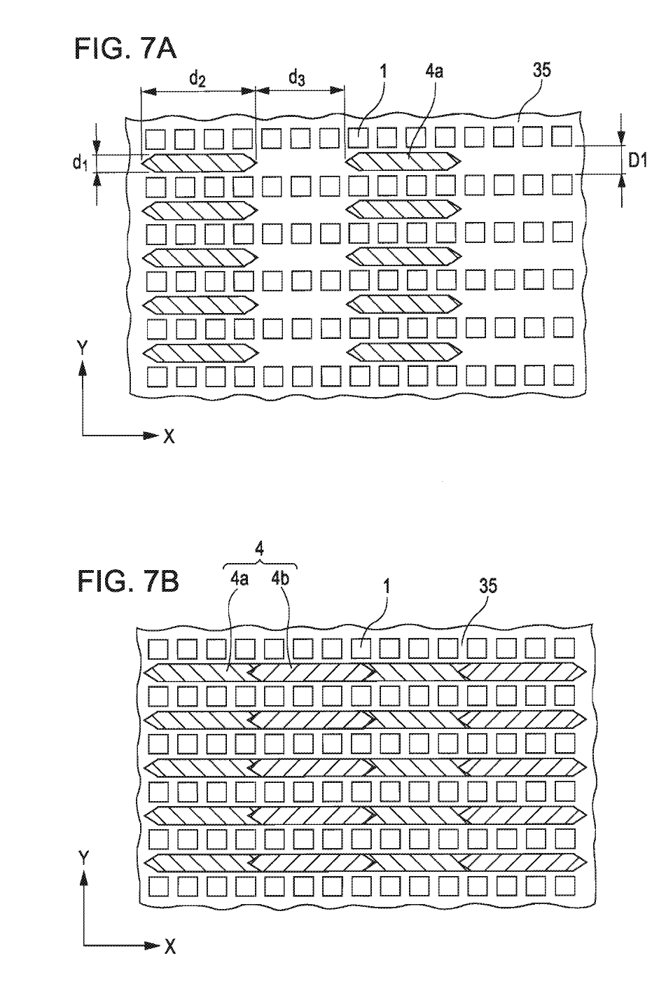

FIGS. 6A to 6D, 7A, and 7B are drawings illustrating a method for forming the auxiliary cathodes in the active matrix display device shown in FIG. 1. FIGS. 6A to 6B are longitudinal sectional views each showing a section taken along VI-VI line in FIG. 2, and FIGS. 7A and 7B are plan views.

[4-A] As shown in FIG. 6A, first, mask positioning marks 48 previously formed on the partition walls 35 are opposed to the mask positioning marks 46a of the mask 40, and the mask 40 is positioned on the TFT circuit substrate 200.

In FIG. 6A, the anodes 3, the organic semiconductor layers 7, and the partition walls 35 have been formed on the TFT circuit substrate 20 through the above-described steps [1] to [3],

[4-B] Next, as shown in FIGS. 6B and 7A, the first micro portions 4a are formed in the regions of the partition walls 35, which are not covered with the mask 40, i.e., the regions corresponding to the respective through parts 47, by vacuum deposition. As a result, a plurality of the first micro portions 4a is substantially linearly formed on the partition walls 35.

[4-C] Next, as shown in FIG. 6C, the mask 40 is moved in a formation direction, i.e., along the long-axis direction (the X-axis direction shown in FIGS. 7A and 7B) of the auxiliary cathodes 4 to be formed so that the mask positioning marks 48 are opposed to the mask positioning marks 46b of the mask 40, and the mask 40 is positioned on the TFT circuit substrate 20.

The space between the two mask positioning marks 46a and 46b, i.e., the amount of parallel movement of the mask 40, is set to be longer than the distance d3 between the adjacent through parts 47 and smaller than the length d2 of the through parts 47. In this case, both ends of the regions corresponding to the through parts 47 overlap the opposing ends (nearer ends) of the adjacent first micro portions 4a.

[4-D] Next, as shown in FIGS. 6D and 7B, the second micro portions 4b are formed in the regions of the partition walls 35, which are not covered with the mask 40, i.e., the regions corresponding to the respective through parts 47, by vacuum deposition. As a result, the second micro portions 4b having the same shape as that of the first micro portions 4a are substantially linearly formed on the partition walls 35.

In step [4-C], the mask 40 is disposed at a position where both ends of the regions of the partition walls, which correspond to the respective through parts 47, overlap the opposing ends (nearer ends) of the adjacent first micro portions 4a. Therefore, the first and second micro portions 4a and 4b are formed so that both ends thereof are connected to each other. As a result, the first and second micro portions 4a and 4b are alternately formed on the partition walls 35 to form the linear auxiliary cathodes 4.

Since the mask 40 also has a plurality of through parts 47 in the width direction of the through parts 47, as shown in FIG. 4, vacuum deposition (steps [4-A] to [4-D]) is performed two times to simultaneously form a plurality (in this embodiment, seven) of the auxiliary cathodes 4.

In this embodiment, the vacuum deposition is performed two times to form the linear auxiliary cathodes 4. However, when the longer auxiliary cathodes 4 than the mask 40 are formed, the vacuum deposition may be performed three or more times.

The shape of the auxiliary cathodes 4 is not limited to a linear shape as long as it is a narrow shape, and may be, for example, a meander curve shape or a frame shape.

The curved auxiliary cathodes 4 may be formed by using the curved through parts 47 provided in the mask 40.

Furthermore, the frame-like auxiliary cathodes 4 may be formed by, for example, rotating the mask 40 through 90° after two times of vacuum deposition, i.e., arranging the mask 40 so that the long-axis direction of the through parts 47 is substantially parallel to the Y-axis direction shown in FIGS. 7A and 7B, followed by further vacuum deposition.

In this embodiment, description is made of the case in which the step [4] of forming the auxiliary cathodes (conductors) 4 is performed between the step [3] of forming the organic semiconductor layers 7 and a next step [5] of forming the cathode 8. However, an embodiment is not limited to this, and the step [4] may be performed between the step [2] of forming the partition walls 35 and the step [3] of forming the organic semiconductor layers 7.

[5] Next, the common cathode 8 is formed to overlap the organic semiconductor layers 7 (luminescent layers 6) and the partition walls 35, i.e., to cover the surfaces of the organic semiconductor layers 7 opposite to the anodes 3 (fourth step).

As a result, a plurality of organic EL elements 1 is formed on the TFT circuit substrate 20.

The cathode 8 may be formed by the above-mentioned vapor-phase process or the liquid-phase process. The forming method is selected in view of the physical properties of the constituent material of the cathode 8, such as the thermal stability and solubility in a solvent, and/or the chemical properties thereof.

In this embodiment, the cathode 8 is formed to overlap the organic semiconductor layers 7 (luminescent layers 6) and the partition walls 35, and thus a mask need not be used. Therefore, in order to form the cathode 8, the vapor-phase process using sputtering or vacuum deposition is preferably used.

[6] Next, the upper substrate 9 is prepared and bonded to the cathode 8 so as to cover the cathode 8.

As a result, the organic EL elements 1 are sealed with the upper substrate 9 to complete the display device 10.

The upper substrate 9 may be bonded to the cathode 8 by drying an epoxy adhesive interposed between the cathode 8 and the upper substrate 9.

The upper substrate 9 functions as a protective substrate for protecting the organic EL elements 1. By providing the upper substrate 9 on the cathode 8, it may be possible to preferably prevent or decrease the contact between the organic EL elements 1 and oxygen and moisture, thereby more securely achieving the effect of improving the reliability of the organic EL elements 1 and preventing degradation and deterioration of the organic EL elements 1.

<Electronic Apparatus>

The display device (organic light-emitting device according to the embodiment of the invention) 10 may be incorporated into various electronic apparatuses.

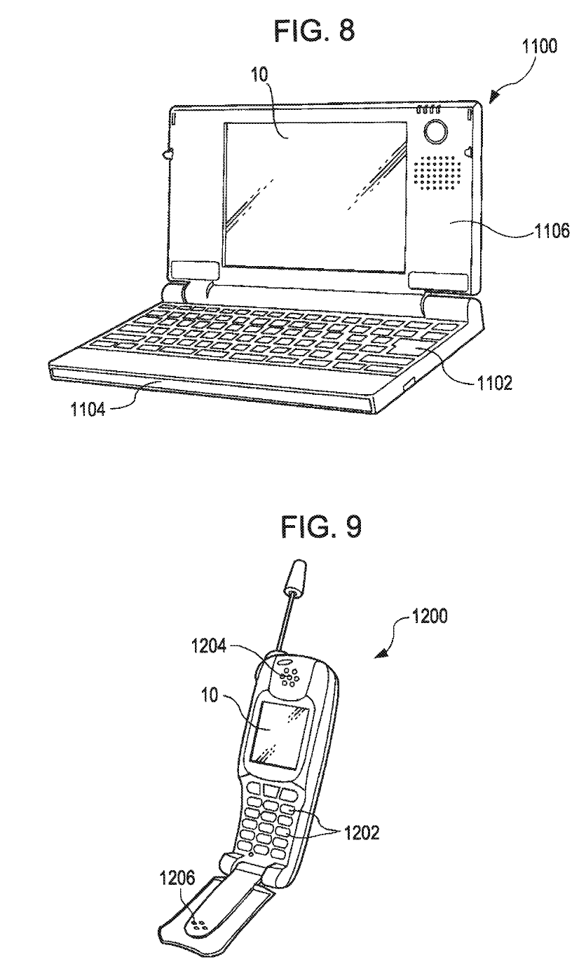

FIG. 8 is a perspective view showing the configuration of a mobile (or notebook-size) personal computer including an electronic apparatus according to an embodiment of the invention.

In this figure, a personal computer 1100 includes a body part 1104 provided with a keyboard 1102, and a display unit 1106 provided with a display part, the display unit 1106 being rotatably supported by the body part 1104 through a hinge structure.

In the personal computer 1100, the display part provided in the display unit 1106 includes the above-described display device 10.

FIG. 9 is a perspective view showing the configuration of a cellular phone (including PHS) including an electronic apparatus according to an embodiment of the invention.

In this figure, a cellular phone 1200 includes a plurality of operating buttons 1202, an ear piece 1204, a mouthpiece 1206, and a display part.

In the cellular phone 1200, the display part includes the above-described display device 10.

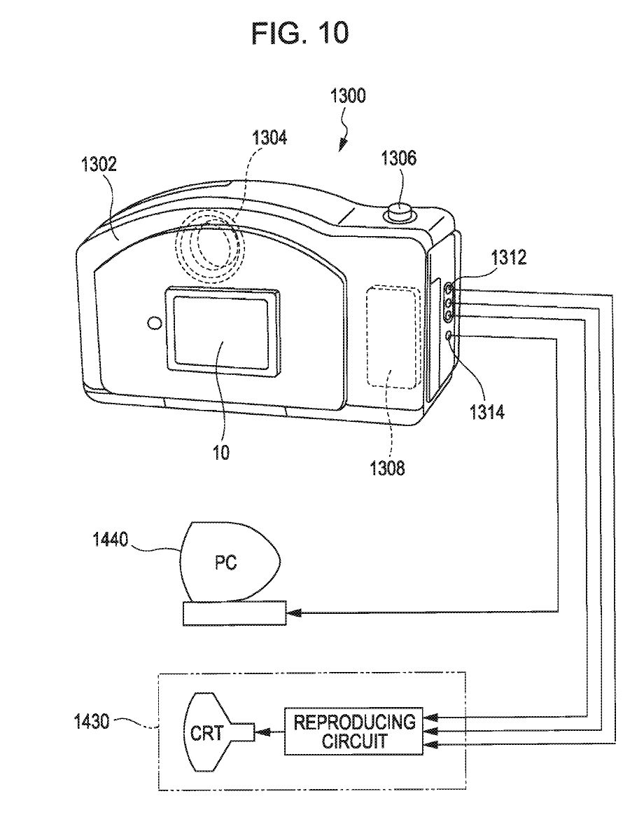

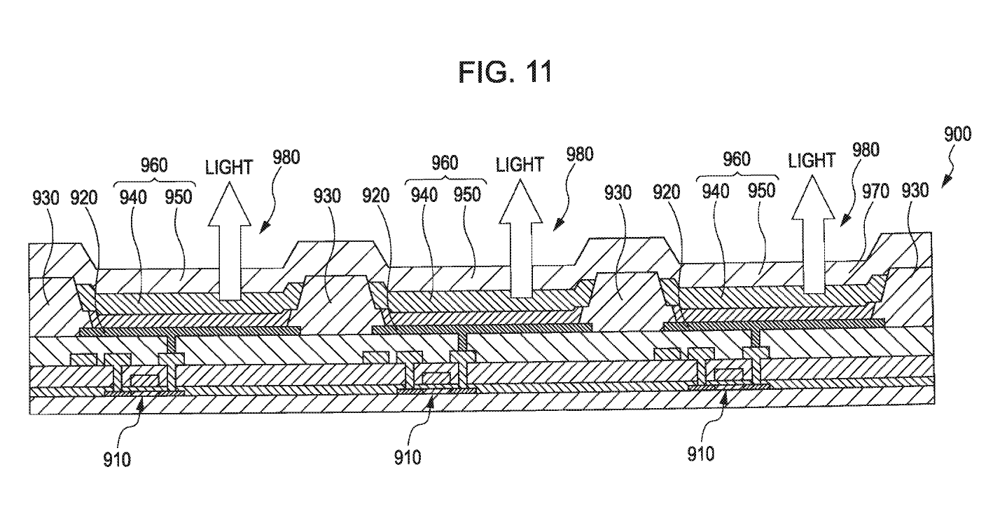

FIG. 10 is a perspective view showing the configuration of a digital still camera including an electronic apparatus according to an embodiment of the invention. This figure also simply shows connections to external devices.

In a usual camera, a silver salt photographic film is exposed to light according to a light image of an object. However, in a digital still camera 1300, a light image of an object is subjected to photoelectric conversion by an imaging device such as CCD (Charge Coupled Device) to produce an imaging signal (image signal).

A display part is provided at the back of a case (body) 1302 of the digital still camera 1300 so that a display is made on the basis of an imaging signal produced by CCD, and the display part functions as a finder for displaying an object as an electronic image.

In the digital still camera 1300, the display part includes the above-described display device 10.

Furthermore, a circuit substrate 1308 is provided in the case. The circuit substrate 1308 includes a memory capable of storing imaging signals.

In addition, a light-receiving unit 1304 including an optical lens (imaging optical system) and CCD is provided on the front side (the back side of the configuration shown in the drawing) of the case 1302.

After an object image displayed on the display part is confirmed by a photographer, a shutter button 1306 is pressed to transmit an imaging signal of CCD at the time to the memory of the circuit substrate 1308 and store the signal therein.

Furthermore, in the digital still camera 1300, video signal output terminals 1312 and a data communication input/output terminal 1314 are provided on the side of the case 1302. As shown in FIG. 10, if required, the video signal output terminals 1312 are connected to a television monitor 1430, and the data communication input/output terminal 1314 is connected to a personal computer 1440. Furthermore, an imaging signal stored in the memory of the circuit substrate 1308 is output to the television monitor 1430 or the personal computer 1440 through a predetermined operation.

Besides the personal computer (mobile personal computer) shown in FIG. 8, the cellular phone shown in FIG. 9, and the digital still camera shown in FIG. 10, an electronic apparatus according to an embodiment of the invention may be applied to, for example, a television, a video camera, a view-finder type or monitor direct-viewing type video tape recorder, a lap-top personal computer, a car navigation system, a pager, an electronic notebook (provided with a communication function), an electronic dictionary, an electric calculator, an electronic game device, a word processor, a work station, a visual telephone, a security television monitor, an electronic binocular, a POS terminal, apparatuses provided with a touch panel (e.g., a cash dispenser of a financial institution and a vending machine), medical devices (e.g., an electronic thermometer, a sphygmomanometer, a blood glucose meter, an electrocardiographic display, an ultrasonograph, and an endoscopic display), a fish finder, various measuring devices, instruments (e.g., instruments of vehicles, aircrafts, and ships), a flight simulator, various other monitors, and projection display devices such as a projector.

Although the method for manufacturing the organic light-emitting device, the organic light-emitting device, and the electronic apparatus according to embodiments of the invention have been described above with reference to the drawings, the present invention is not limited to these.

The method for manufacturing the organic light-emitting device according to an embodiment of the invention may further include at least one additional step for a desired purpose.

The entire disclosure of Japanese Patent Application No. 2005-355430, filed Dec. 8, 2005 is expressly incorporated by reference herein.

What is claimed is:

1. A method for manufacturing an organic light-emitting device comprising:
preparing a substrate on one of the surfaces of which a plurality of individual electrodes is provided;
forming frame-shaped partition walls partitioning the individual electrodes;
forming organic semiconductor layers inside the respective partition walls, the organic semiconductor layers each containing a luminescent layer;
forming a common electrode so that it overlaps the organic semiconductor layers and the partition walls; and
forming narrow conductors on the partition walls by a plurality of times of vacuum deposition between the formation of the partition walls and the formation of the common electrode, the narrow conductors having the function to decease the electric resistance of the whole common electrode by contact with the common electrode;
wherein in forming the conductors, the conductors are formed in divided micro strip portions connected to each other using the same mask.

2. The method according to claim 1, wherein the conductors are linear and formed by moving the mask in a direction in which the conductors are formed, at each time of the vacuum deposition.

3. The method according to claim 2, wherein the conductors are formed by forming a plurality of first micro portions to be linearly arranged an then further forming a plurality of second micro portions to connect the ends of the first micro portions.

4. The method according to claim 3, wherein each of the micro portions are widened at both ends thereof.

5. The method according to claim 3, wherein the mask includes a support substrate and a plurality of chips fixed to the support substrate and having apertures corresponding to the respective micro portions, and the support substrate and the chips are composed of materials having substantially the same thermal expansion coefficient.

6. The method according to claim 5, wherein the micro portions are linear and satisfy the relation 2(A+B)<d1<D1−2(A+B) wherein d1 is the width (μm) of the apertures, D1 is the width (μm) of the partition walls, A is alignment accuracy (μm) between the support substrate and the chips, and B is alignment accuracy (μm) between the mask and the substrate.

7. The method according to claim 5, wherein the micro portions are linear and satisfy the relation d2>D2/X+2(A+B) wherein d2 is the length (μm) of the apertures, D2 is the length (μm) of the conductors, X is the number of partitions D2, A is alignment accuracy (μm) between the support substrate and the chips, and B is alignment accuracy (μm) between the mask and the substrate.

8. The method according to claim 1, wherein the common electrode is formed using a transparent conductive material, and the conductors are formed using a metal material having a smaller electric resistance than that of the transparent conductive material.

9. An organic light-emitting device manufactured by the method according to claim 1.

10. The organic light-emitting device according to claim 9, wherein the organic light-emitting device is a top-emission structure device including the individual electrodes serving as anodes, and the common electrode serving as a cathode.

11. An electronic apparatus comprising the organic light-emitting device according to claim 9.
